(19) United States
(12) Patent Application Publication
(10) Pub. No.: US 2026/0055532 A1
(43) Pub. Date: Feb. 26, 2026

(54) CHAMBER AND METHOD FOR CONTROLLING FILM DEFECTS AT AN EDGE AREA OF A SUBSTRATE

(71) Applicant: Applied Materials, Inc., Santa Clara, CA (US)

(72) Inventors: Ruiying HAO, Santa Clara, CA (US); Raghuveer Satya MAKALA, Santa Clara, CA (US); Tomohiko KITAJIMA, San Jose, CA (US); Abhishek DUBE, Fremont, CA (US); Zhepeng CONG, San Jose, CA (US); Thomas KIRSCHENHEITER, Tempe, AZ (US); Zuoming ZHU, Sunnyvale, CA (US); Ala MORADIAN, Sunnyvale, CA (US); Maribel MALDONADO-GARCIA, Valle de Santiago (MX); Erica DE LEON SANCHEZ, Santa Clara, CA (US); Jenn-Yue WANG, Fremont, CA (US)

(21) Appl. No.: 18/813,891

(22) Filed: Aug. 23, 2024

(51) Int. Cl. C30B 25/16; C30B 25/08; C30B 25/10; C30B 25/12

(52) U.S. Cl. CPC C30B 25/16; C30B 25/08; C30B 25/10; C30B 25/12

(57) ABSTRACT

Disclosed herein is a processing chamber. In one embodiment, the processing chamber includes a substrate support assembly comprising a susceptor configured to support a substrate within a processing region within the processing chamber, a deposition gas channel configured to flow a deposition gas across an upper surface of the substrate, an auxiliary gas channel configured to flow an auxiliary gas toward an edge area of the substrate, and a separator disposed between the deposition gas channel and the auxiliary gas channel.

### BACKGROUND

### Field

The present disclosure relates to a processing chamber and method for reducing defects in an epitaxial film at a bevel or edge area of a substrate, and, more specifically, relates to a processing chamber and method capable of reducing the defects by controlling the film thickness and/or the growth rate at the edge area of a substrate.

### Description of the Related Art

Epitaxy (EPI) has been widely used in depositing materials on surfaces of semiconductor substrates and devices. In an EPI chamber designed for an EPI deposition process, a deposition gas containing a precursor is flowed into an internal volume where a substrate is positioned on a susceptor. A plasma may be used to facilitate the growth of epitaxial layers on the substrate. An epitaxial layer may be grown on a same material, such as Si on Si growth, which may be known as homoepitaxy. An epitaxial layer may also be grown on a different substrate, such as AlAs on GaAs, which may be known as heteroepitaxy. The epitaxial layer can grow on any area of a substrate that has been exposed to the deposition gas.

A known problem in heteroepitaxy is a mismatch of lattice constants between an EPI layer and a substrate. For example, in a Si/SiGe superlattice hetero structure, the lattice constant is 5.431A for Si and 5.658A for Ge. This lattice mismatch can cause compressive stress and wafer bow which will increase with the composition of Ge in a deposited film. The stress can induce epitaxial defects in the deposited EPI films. For example, a cross hatching defect is normally formed at the wafer bevel and edge area initially, and then may propagate inwardly to other areas of the deposited EPI film. The cross hatching defect becomes worse with the increase of the Ge concentration and/or the SiGe thickness.

Thus, a need exists for an improved EPI processing chamber and method that are capable of reducing the cross-hatching related defects around the bevel or edge area of a substrate.

### SUMMARY

Disclosed herein is a processing chamber. In one embodiment, the processing chamber includes a substrate support assembly comprising a susceptor configured to support a substrate within a processing region within the processing chamber, a deposition gas channel configured to flow a deposition gas across an upper surface of the substrate, an auxiliary gas channel configured to flow an auxiliary gas toward an edge area of the substrate, and a separator disposed between the deposition gas channel and the auxiliary gas channel.

In another embodiment, the processing chamber includes a substrate support assembly comprising a susceptor configured to support a substrate within a processing region within the processing chamber, a deposition gas channel configured to flow a deposition gas across an upper surface of the substrate, an auxiliary gas channel, and a gas distribution plate positioned above the susceptor. The auxiliary gas channel is configured to flow the auxiliary gas into a plenum above the gas distribution plate, and the gas distribution plate has a plurality of gas conduits positioned to flow the auxiliary gas from the plenum toward an edge area of the substrate.

In yet another embodiment, the processing chamber includes a substrate support assembly comprising a susceptor configured to support a substrate within a processing region within the processing chamber, a deposition gas channel configured to flow a deposition gas across an upper surface of the substrate, and a purge gas channel configured to flow a purge gas into a space below the susceptor, wherein the susceptor has a plurality of apertures disposed in a peripheral area thereof and configured to allow the purge gas to pass through to the edge area of the substrate positioned on the susceptor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present disclosure.

FIG. 2 illustrates a schematic cross-sectional view of an EPI processing chamber, according to an embodiment of the present disclosure.

FIG. 3 illustrates a schematic top view of a substrate according to an embodiment of the present disclosure.

FIG. 4A illustrates a schematic configuration of an auxiliary gas flow system of an EPI processing chamber, according to an embodiment of the present disclosure.

FIG. 4B illustrates another schematic configuration of the auxiliary gas flow system of an EPI processing chamber, according to an embodiment of the present disclosure.

FIG. 5 illustrates a schematic configuration of a thermal module of an EPI processing chamber, according to an embodiment of the present disclosure.

FIG. 6 illustrates a schematic configuration of a purge gas flow system of an EPI processing chamber, according to an embodiment of the present disclosure.

FIG. 7 illustrates a schematic configuration of an etchant gas flow system of an EPI processing chamber, according to an embodiment of the present disclosure.

FIG. 8 illustrates a method for processing a substrate, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Disclosed herein is an epitaxy (EPI) processing chamber and an EPI processing method capable of reducing film defects at an edge area of a substrate. An edge area as used in the present disclosure may be understood as an annular area along the edge of a substrate. A width of the annular area may be no greater than a few millimeters, such no greater than 2 mm, no greater than 1 mm, or no greater than 0.5 mm, which is measured from the edge of the substrate. The EPI processing chamber includes hardware configured to control the film thickness or the film growth rate at the edge area of a substrate. The EPI processing chamber and processing method as set forth in various embodiments of the present disclosure can reduce the instances that the cross hatching related defects may prorogate into the bulk area of an EPI film deposited a substrate.

In an example, the EPI processing chamber includes gas flow systems configured to flow a dilution gas, a purge gas, or an etchant gas toward the bevel or edge area of the substrate to control the thickness of the film formed on the bevel or the edge area. The EPI processing chamber and method may also utilize a radiant heater to adjust the temperature at the bevel of edge area. The EPI processing chamber and method as set forth in various embodiment of the present disclosure can reduce the defects at the bevel and the edge area of a substrate, mitigate the impact of the defects on a main area of the substrate, and allow a film stack to grow thicker without experiencing a cross hatching defect.

In an example, the processing chamber includes an auxiliary gas flow system configured to flow a dilution gas toward an edge area of a substrate in the EPI processing chamber. The dilution gas is provided to reduce the concentration of at least an element contained in the deposition gas. The element may include silicon, carbon, or a dopant contained in the deposition gas. The dilution gas is flowed toward the edge area such that the growth rate of the film thickness is reduced at the edge area. The dilution gas may be flowed toward the edge area from gas nozzles above the substrate or from gas nozzles surrounding the substrate.

In an example, the EPI processing chamber includes a purge gas flow system configured to flow a purge gas into a space under a substrate support assembly. A plurality of apertures, such as slits, are formed in a substrate support assembly around the edge area of the substrate. The plurality of apertures allow the purge gas to pass through, which can disperse the deposition gas around the edge area, thus reducing the film growth rate at the edge area.

In an example, the EPI processing chamber includes an etchant gas flow system configured to flow an etchant gas toward the edge area. The etchant gas flow system may have a gas nozzle disposed adjacent to an exhaust outlet of the processing chamber. The etchant gas may also be flowed into the EPI processing chamber together with the purge gas via the purge gas flow system.

In an example, the EPI processing chamber includes an auxiliary heat source configured to target the edge area of the substrate. The auxiliary heat source may include a plurality of radiative heaters arranged along a peripheral area of an upper dome of the EPI processing chamber. The radiative heaters are configured to emit radiation of a predetermined wavelength depending on the materials to be processed in the EPI processing chamber. To control the temperature at the edge area, the EPI processing chamber may further include a perimeter thermal sensor, such as a pyrometer, disposed at a peripheral area of a lid of the EPI processing chamber. The perimeter thermal sensor is configured to measure the temperature of the edge area, which can be used to control the auxiliary heat source.

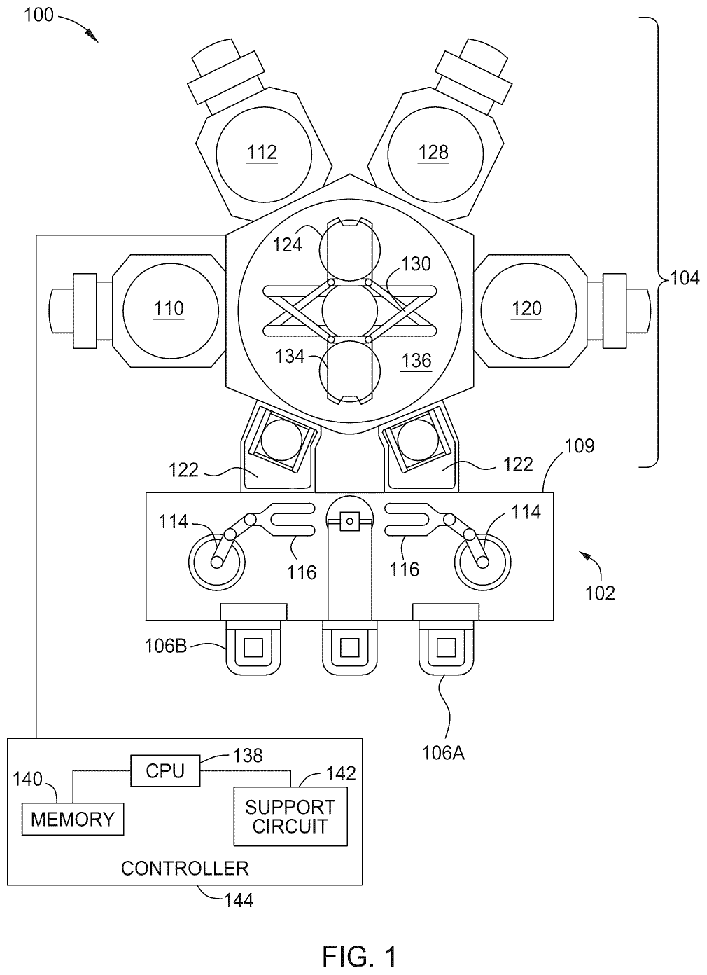

FIG. 1 illustrates a schematic top view of a processing system 100 for processing a substrate, according to one or more embodiments. In an embodiment, the processing system 100 includes an EPI chamber configured to implement an epitaxial growth method according to various embodiments of the present disclosure. The processing system 100 includes a processing platform 104 coupled with a factoring interface 102 and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, and 128, one or more load lock chambers 122, and a transfer chamber 136 that is coupled to the one or more load lock chamber 122. The plurality of processing chambers 110, 112, 120, and 128 may include a plasma enhanced chemical vapor deposition (PECVD) chamber, an epitaxy (EPI) chamber, a rapid thermal processing (RTP) chamber, a reactive ion etching (RIE) chamber, or other suitable chamber. The transfer chamber 136 can be maintained under vacuum, or can be maintained at an ambient (e.g., atmospheric) pressure. Two load lock chambers 122 are shown in FIG. 1.

Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The factory interface 102 is coupled to the transfer chamber 136 through the load lock chambers 122. In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

The controller 144 is coupled to the processing system 100 and is used to control processes and methods, such as the operations of the methods described herein (for example the operations of the methods as described in other parts of the present disclosure). The controller 144 includes a central processing unit (CPU) 138, a memory 140 containing instructions, and support circuits 142 for the CPU. The controller 144 controls various items directly, or via other computers and/or controllers.

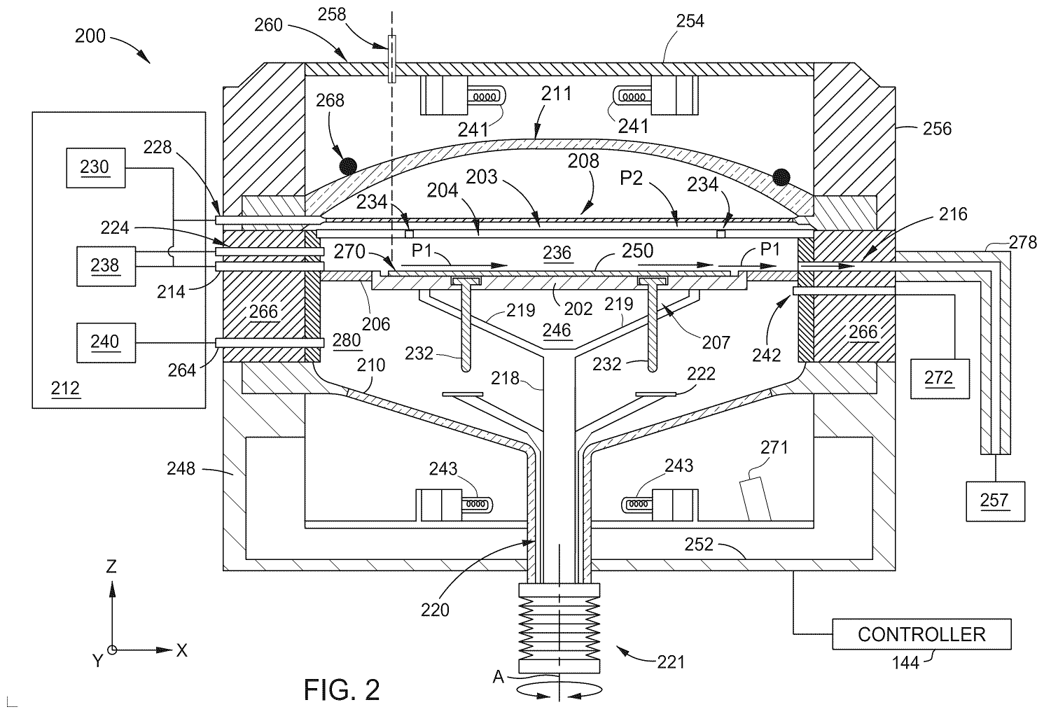

FIG. 2 illustrates a schematic cross-sectional view of an EPI processing chamber 200 according to an embodiment. The EPI processing chamber 200 functions as a deposition chamber to grow an EPI layer on a substrate 250 according to various embodiments of the present disclosure. One or more of the processing chambers 110, 112, 120, and 128 shown in FIG. 1 is configured as the processing chamber 200. As shown, the controller 144 is in communication with the processing chamber 200 and is used to control processes and methods of at least the processing chamber 200.

The processing chamber 200 includes an upper body 256, a lower body 248, and a side body 266 disposed between the lower body 248 and the upper body 256. The upper body 256, the side body 266, and the lower body 248 enclose an internal volume, inside which a plurality of components, parts, and systems are disposed. For example, a substrate support assembly 246 is disposed in the processing chamber 200. The substrate support assembly 246 includes a susceptor 202 having an upper surface configured to support a substrate 250. The substrate support assembly 246 is protected by an upper window 211 (such as an upper dome) and a lower window 210 (such as a lower dome). An edge ring 206 is disposed between the substrate support assembly 246 and the side body 266 to cover any gaps therebetween. In some embodiments, the edge ring 206 may be referred to as a pre-heat ring that pre-heats gas flowing over it.

A plurality of upper heat sources 241, and a plurality of lower heat sources 243 are also disposed in the chamber. The plurality of upper heat sources 241 are disposed between the upper window 211 and a lid 254. The plurality of lower heat sources 243 are disposed between the lower window 210 and a chamber floor 252. The upper window 211 is an upper dome extending between walls of the upper body 256 and is formed at least partially of an energy transmissive material, such as quartz. The lower window 210 is a lower dome extending between walls of the lower body 248 and is formed at least partially of an energy transmissive material, such as quartz.

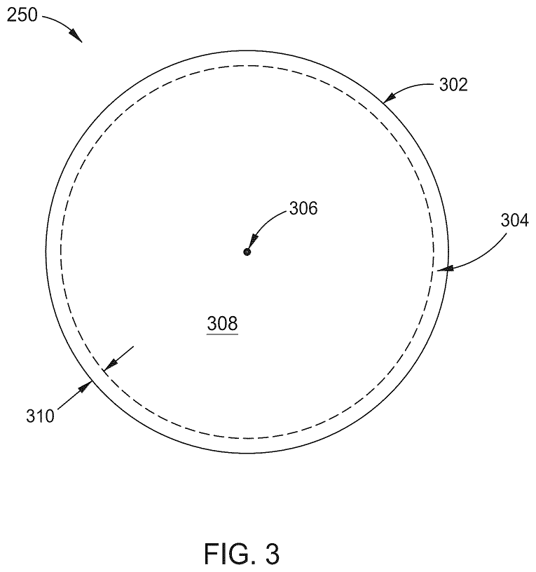

In an embodiment, an auxiliary heat source 268 is disposed at the peripheral area of the upper window 211 and configured to heat an edge area 270 of the substrate 250 positioned on the upper surface of the susceptor 202. The auxiliary heat source 268 may be a radiant heater configured to direct radiant heat toward the edge area 270 of the substrate. The edge area 270 will be further described with reference to FIG. 3. The auxiliary heat source 268 may be disposed at a location adjacent to the edge area 270 or at any other suitable locations. The auxiliary heat source 268 may be a ring-shaped, radiant heater.

One or more thermal sensors 271 are used to detect a thermal condition of the processing chamber 200. The one or more thermal sensors 271 may include one or more cameras, one or more pyrometers, one or more thermoelectric sensors, and/or one or more thermal labels. The one or more thermal sensors 271 can be mounted, for example, below the lower window 210 (as shown in FIG. 2), or above the upper window 211 (such as on or in the lid 254), or any other suitable place in the processing chamber 200. In one embodiment, a pyrometer 258 is mounted above the upper window 211 and at a peripheral area 260 of the lid 254. The pyrometer 258 is configured to remotely measure the temperature of the edge area 270 of the substrate 250.

The substrate support assembly 246 is disposed between the upper window 211 and the lower window 210. The substrate support assembly 246 is configured to rotate the substrate 250 during a process. The substrate support assembly 246 is supported by an inner shaft 218 coupled with a motion assembly 221. The motion assembly 221 includes one or more actuators and/or adjustment devices that provide movement and/or adjustment for the inner shaft 218, which, in turn, moves the substrate support assembly 246 and the substrate 250. The substrate support assembly 246 is coupled to the inner shaft 218 through one or more arms 219. A plurality of lift pin holes 207 are disposed in the substrate support assembly 246 and sized to accommodate a lift pin assembly 232 that is used to lift the substrate 250 from the substrate support assembly 246. The lift pin assembly 232 is coupled with the actuator 221 via pedestals 222 of an outer shaft 220.

In an embodiment, the processing chamber 200 includes a first plenum 203 configured to contain an auxiliary gas P2 and a second plenum 236 configured to contain a deposition gas P1. In an example, the deposition gas P1 may be silicon or carbon containing gas configured to deposit a layer of a materials on the substrate 250. For example, the deposition gas P1 may include precursors for SiGe, SiGeC, SiGeB, GaAs, GaN, AlN, GaAlN, or any other suitable film. The precursors may include SiH₄, Si₂H₆, H₂SiCl₂, HCl₃Si, GeH₄, monomethylsilane, B₂H₆, PH₃, trimethyl aluminum, trimethylgallium, NH₃, GaC₁₃ and AsH₃. The auxiliary gas P2 may be a dilution gas configured to dilute at least an element of the deposition gas P1, such as SI, Ge, C, a dopant, or other suitable element. In an embodiment, the dilution gas may include gases that would not cause the deposition of a targeted EPI film. For example, when the deposition gas includes Si and SiGe for growing a SiGe film on a substrate, the dilution gas may include SiH₄, Si₂H₆, H₂SiCl₂, HCl, Cl₂, or H₂. In an example, the dilution gas may be an inert gas, such as nitrogen (N₂), helium (He), or any other suitable inert gas.

The first plenum 203 and the second plenum 236 are separated by a gas distribution plate 204. The first plenum 203 is disposed between the upper window 211 and the gas distribution plate 204. An optional containing plate 208 may be disposed below the upper window 211 to form the first plenum 203 with the gas distribution plate 204. The containing plate 208 may be coupled to the upper body 256 and may be made of a material similar as that of the upper dome 211. In another embodiment, the containing plate 208 may be part of the gas distribution plate 204.

The second plenum 236 is disposed between the gas distribution plate 204 and the substrate support assembly 246. The gas distribution plate 204 is configured to allow the auxiliary gas P2 to flow from the first plenum 203 into the second plenum 236 through a plurality of gas conduits 234 disposed in the gas distribution plate 204. The plurality of gas conduits 234 are positioned in the gas distribution plate 204 to flow gas from the first plenum 203 toward the edge area 270 of the substrate 250 positioned on the upper surface of the susceptor 202. As a result, the edge area 270 of the substrate 250 can be covered by the auxiliary gas P2.

The processing chamber 200 includes a gas flow system 212 configured to flow a plurality of gases into the processing chamber 200. The gas flow system 212 includes a plurality of gas channels and gas sources. For example, the gas flow system 212 includes a dilution gas source 230 coupled with an elevated gas channel 228 and a side gas channel 214. The elevated gas channel 228 is disposed above the substrate 250 and flows the dilution gas P2 to the first plenum 203. The side gas channel 224 is disposed at substantially the same level as the susceptor 202 and is configured to flow the dilution gas P2 horizontally to the edge area 270 of the substrate 250 positioned on the upper surface of the susceptor 202.

The gas flow system 212 also includes a deposition gas source 238 coupled with a side gas channel 224. The side gas channel 224 is disposed between the elevated gas channel 228 and the side gas channel 214 and is configured to flow the deposition gas P1 horizontally across the substrate 250 positioned on the upper surface of the susceptor 202.

The gas flow system 212 also includes a purge gas source 240 coupled with a purge gas channel 264. The purge gas channel 264 is disposed under the susceptor 202 and configured to flow a purge gas into a space 280 under the susceptor 202. A purge gas may include any non-reactive gas, such as argon, nitrogen, or any other suitable gas.

The gas flow system 212 also includes an etchant gas channel 242 disposed adjacent to an exhaust outlet 216 of the processing chamber. The etchant gas channel 242 is coupled with an etchant gas source 272 and is configured to flow an etchant gas horizontally toward an edge area of the substrate 250. In an embodiment, the purge gas source 240 may include both the purge gas and the etchant gas and provide both the purge as and the etchant gas into the space 280 via the gas channel 264. The etchant gas may include a chlorine based gas, such as HCl or Cl₂. The etchant gas may also include hydrogen H₂.

The gas exhaust outlets 216 are connected to an exhaust system 278 and an exhaust pump 257. The exhaust system 278 is disposed on an opposite side of the deposition gas channel 224 and configured to pump out the effluent gases from the processing chamber 200. When the etchant gas channel 242 is disposed adjacent to the exhaust outlets 216, the etchant gas can be quickly removed from the processing chamber before it spreads to other regions of the processing chamber.

FIG. 3 illustrates a schematic top view of a substrate 250, according to an embodiment of the present disclosure. The substrate 250 includes a main surface area 308 surrounded by an edge area 304. Both the main surface area 308 and the edge area 304 share a common center 306. The edge area 304 starts from an outer edge 302 of the substrate 250. The outer edge 302 may also be known as the bevel of a substrate. The edge area 304 is shaped like an annular area with a width 310 of no greater than 2 mm, 1 mm, 0.5 mm, or even a smaller number. The main surface area 308 and the edge area 304 form the top surface of the substrate 350 that is used for the growth of an EPI layer. In an embodiment, the main surface area 308 has a crystal orientation that is different from the crystal orientation of the outer edge 302. A cross hatch defect may be originated at the edge area 304 and then propagate into the main surface area 308 if not mitigated properly.

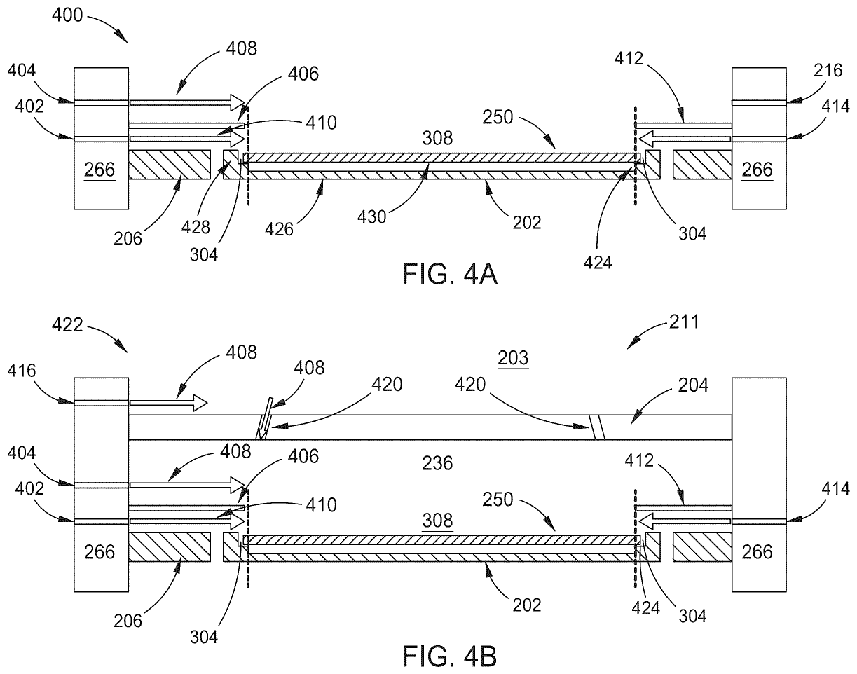

FIG. 4A illustrates a schematic configuration of a gas flow system 400, according to an embodiment of the present disclosure. The gas flow system 400 is configured to flow an auxiliary gas, such as a dilution gas 410, into the processing chamber. The auxiliary gas flow system 400 includes a side gas channel 402 disposed within a side section 266 of a processing chamber. The side gas channel 402 flows the dilution gas 410 toward the edge area 304 of the substrate 250. The side gas channel 402 may be disposed substantially at the same level as the substrate 250. In an embodiment, the gas flow system 400 may include another side gas channel 414 disposed adjacent to an exhaust outlet 216 of the processing chamber. A separator 412 is disposed above the side gas channel 414. In another embodiment, the gas flow system 400 may include a plurality of side gas channels disposed around the edge area 304 of the substrate 250.

A deposition gas channel 404 may be disposed above the side gas channel 402 or may be disposed side by side with the side gas channel 402. The deposition gas channel 404 flows a deposition gas 408 into the processing chamber across the surface of the substrate 250 positioned on the upper surface of the susceptor 202. A separator 406 is disposed between the deposition gas channel 404 and the side gas channel 402. The separator 406 may be made of a material that is resistant to the deposition gas 408 and the dilution gas 410, such as alumina, quartz, or any other suitable material. The separator 406 prevents the dilution gas 410 and the deposition gas 408 from mixing and guides the dilution gas 410 to the edge area 304. The separator 406 can be a ledge structure that extends horizontally from the side section 266 to a location adjacent to the edge area 304, such as over the edge ring 206 and a radial edge of the susceptor 202. In some embodiments, the separator 406 can be ring shaped or arc shaped. The separator 406 is configured not to interfere with the loading or unloading of the substrate 250. For example, the separator 406 may have a length similar to the edge ring 206 and does not extend into the space above the substrate 250 to permit the substrate 250 to be freely loaded onto or unloaded from the susceptor 202.

In the example shown in FIG. 4A, the susceptor 202 includes a bottom section 426, a pedestal 424, and an edge wall 428. The substrate 250 is supported by the pedestal 424 and is surrounded by the edge wall 428. The pedestal 424 raises the substrate 250 above the bottom section 426 such that a gap 430 is formed between the substrate 250 and the bottom section 426. In an embodiment, the separator 406 extends into a region that is between the edge ring 206 and the edge wall 428. The separator 406 may extend into a region above the edge wall 428. To avoid any interference with the loading and unloading of the substrate 250, the separator 406 does not extend beyond the edge wall 428. The separator 406 may be disposed substantially along the entire perimeter of the side section 266 and around the perimeter of the susceptor 202 to separate any premature mixing between the deposition gas 408 and the dilution gas 410.

FIG. 4B illustrates a schematic configuration of an auxiliary gas flow system 422, according to an embodiment of the present disclosure. Comparing with the auxiliary gas flow system 400 of FIG. 4A, the auxiliary gas flow system 422 further includes an elevated gas channel 416 disposed above the substrate 250 and the deposition gas channel 404. The elevated gas channel 416 flows the auxiliary gas 408 into the processing chamber from a location above the substrate 250.

The auxiliary gas flow system 422 further includes a gas distribution plate 204 disposed between the elevated gas channel 416 and the deposition gas channel 404. The gas distribution plate 204 extends between the side sections 266 of the processing chamber and separates an internal volume of the processing chamber into a first plenum 203 and a second plenum 236. The gas distribution plate 204 includes a plurality of downwardly facing gas conduits 420, which are oriented in a direction toward the edge area 304, e.g., the outer 2 mm, of the substrate 250. The gas conduits 420 may be disposed at locations adjacent to the side gas channel 404 or may be disposed generally following the edge area 304 of the substrate 250. In an embodiment, the first plenum 203, which is formed between the upper dome 211 and the gas distribution plate 204, may have a higher pressure than the second plenum 236. As a result, the auxiliary gas 408 can flow from the first plenum 203 into the second plenum 236 via the gas conduits 420 and in a direction toward the edge area 304 of the substrate 250.

In an embodiment, the gas conduits 420 may be disposed at a peripheral area of the gas distribution plate 204 that is within the edge area 304 of the substrate 250. For example, the gas conduits 420 may be positioned only at the peripheral area of the gas distribution plate 204 such that no gas conduits 420 are positioned in a central area of the gas distribution plate 420. The gas conduits 420 are oriented radially outward and downward to guide the dilution gas 408 in a direction away from the main surface area 308 of the substrate 250. The gas conduits 420 may be disposed at an angle with respect to a vertical axis of the susceptor 202. For example, the gas conduits may be configured at between about 5 degrees and about 45 degrees, such as between about 10 degrees and about 35 degrees, with respect to the vertical axis of the susceptor 202. In another embodiment, the gas conduits 420 are disposed directly above the edge area 304 and are oriented downward toward the edge area 304. The diameter of the gas conduits 420 may be constant or may be gradually decreasing along a downward direction. In an embodiment, the side gas channel 402, and the separator 406 may be optional components of the auxiliary gas flow system 422 and may be removed from the auxiliary gas flow system 422.

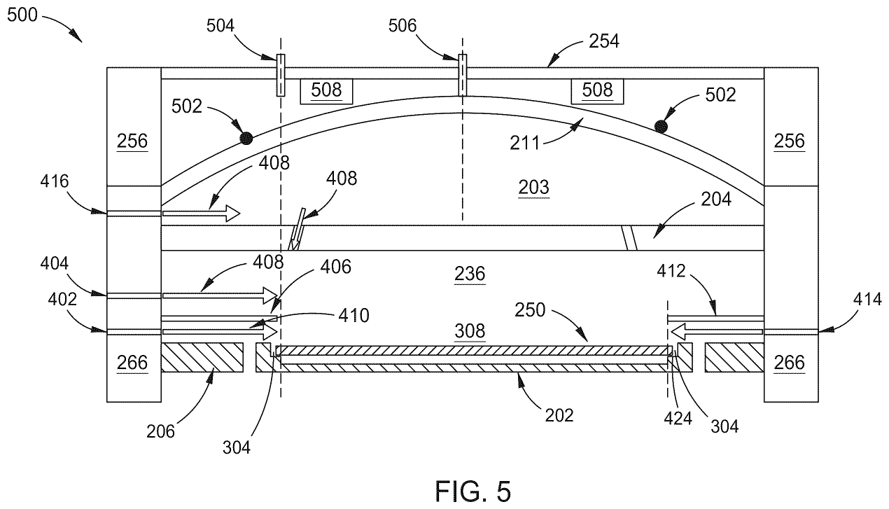

FIG. 5 illustrates a schematic configuration of a thermal module 500 of an EPI processing chamber, according to an embodiment of the present disclosure. The thermal module 500 includes a plurality of heating sources 508, 502 and a plurality of thermal sensors 504, 506. In an embodiment, the heating sources 508 are configured to heat the main surface area 308 of the substrate 250. The heating sources 508 may include radiative heating sources, such as a radiant lamp, UV, LED, laser, or any other suitable heating source. The heating sources 502 are configured to heat the edge area 304 of the substrate 250. The heat sources 502 may be include radiative heating sources, such as a radiant lamp, UV, LED, laser, or any other suitable heating source. The heating sources 502 may radiate electromagnetic radiations in different wavelengths. In an embodiment, the heating sources 502 are configured to heat the edge area 304 to a temperature that is lower than a temperature of the surface area 308. The heating sources 502 may be arranged in a ring shape along the peripheral area of the upper dome 211. The heating sources 508 are surrounded by the heating sources 502. The heating sources 508 may also be arranged in a ring shape that is concentric with the heating sources 502.

The thermal module 500 may include a plurality of thermal sensors 506, 504 disposed on a lid 254 of the possessing chamber. The thermal sensors 506 and 504 may include a pyrometer or any other suitable thermal sensor. In an embodiment, the thermal sensors 506 are configured to detect a temperature of the surface area 308. At least one thermal sensor 506 may be disposed at the center of the lid 254. In an embodiment, the thermal sensors 504 are configured to detect a temperature of the edge area 304. The thermal sensors 504 may be disposed around a peripheral area of the lid 254 and directly point toward the edge area 304.

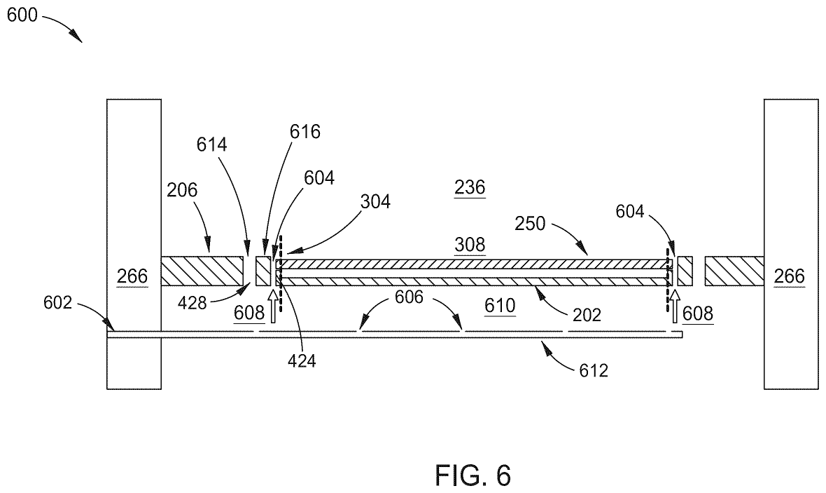

FIG. 6 illustrates a schematic configuration of a purge gas flow system 600 of a processing chamber, according to an embodiment of the present disclosure. The purge gas flow system 600 is configured to flow a purge gas into a space 610 that is below the susceptor 202. The purge gas flow system 600 may also flow a purge gas or an etchant gas in to the space 610. The purge gas flow system 600 includes a gas channel 602 disposed within the side section 266 of the processing chamber. The purge gas channel 602 may include a dispensing pipe 612 extending into the space 610. For example, the dispensing pipe 612 extends at least into a central region of the space 610 below the susceptor 202. The dispensing pipe 612 is coupled with the gas channel 602 and includes a plurality of gas dispensing orifices 606. In another embodiment, the dispensing pipe 612 may be circular of semicircular with the gas dispensing orifices 606 directed toward the edge area 304 of the substrate 250. The space 610 may have a higher pressure than the second plenum 236 such that the purge gas 608 can be pushed into the second plenum 236. The dispensing pipe 612 is capable of dispensing a purge gas 608 around the edge area 304 of the substrate 250. In an embodiment, a plurality of apertures 604, such as slits, are formed in the pedestal 424 of the susceptor 202 at locations along an inner perimeter 616 of the edge wall 428 of the susceptor 202. The plurality of apertures 604 are positioned in the pedestal 424 within 3 mm of the radial edge of the substrate 250. Another gas passage 614 may be formed between the edge ring 206 and the edge wall 428. Both the apertures 604 and the gap 614 allow the purge gas 608 to pass through and reach the edge area 304. As a result, the edge area 304 can have a diluted deposition gas, causing the growth rate of the EPI layer at the edge area 304 to slow down. In an embodiment, the air passage 614 is wider than that of the apertures 604 as the air passage 614 also needs to maintain enough clearance between the susceptor 202 and the edge ring 206. The apertures 604 may be disposed substantially along the entire inner perimeter 616 of the edge wall 428.

In an embodiment, an etchant gas may be flowed into the space 610 and then reach the edge area 304 via the slits 604. The etchant gas can etch away a limited amount of the deposited EPI layer, thus lowering the thickness of the EPI layer at the edge area 304. In an embodiment, the purge gas and the etchant gas may be flowed into the space 610 simultaneously or sequentially.

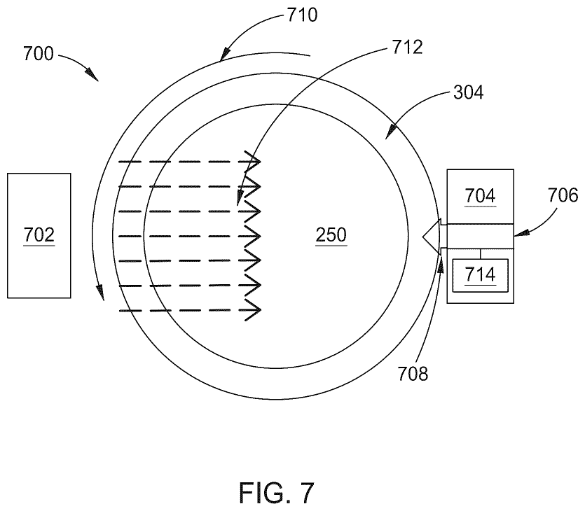

FIG. 7 illustrates a schematic configuration of an etchant gas flow system 700 of a processing chamber, according to an embodiment of the present disclosure. As discussed before, a processing chamber has a deposition gas channel 702 and an exhaust outlet 704, which are positioned at opposite sides of the processing chamber. A deposition gas 712 flows into the processing chamber and across the substrate 250 in a direction from the deposition gas channel 702 toward the exhaust outlet 704.

In an embodiment, the etchant gas flow system 700 includes an etchant gas channel 706 disposed adjacent to the exhaust outlet 704 of the processing chamber. The etchant gas channel 706 flows an etchant gas 708 toward the edge area 304 of the substrate 250. As the substrate 250 rotates in a direction 710, the entire edge area 304 is sequentially subject to the etchant gas 708, even though the etchant gas 708 is released only at one location or a few locations in the processing chamber. Flowing the etchant gas 708 at a location adjacent to the exhaust outlet 704 is advantageous because the etchant gas 708 can be quickly pumped out via the exhaust outlet 704 and have less adverse impact on the EPI growing processing occurred in other parts of the processing chamber.

A remote plasma source 714 may be coupled with the etchant gas channel 706 to energize the etchant gas 708. As a result, the etchant gas 708 includes radicals, such as Cl radicals, which can etch an EPI layer effectively.

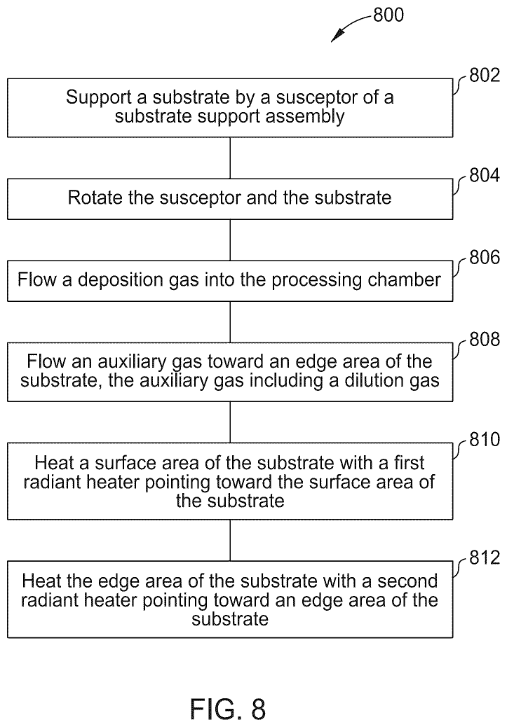

FIG. 8 illustrates a method 800 for processing a substrate according to an embodiment of the present disclosure. The method 800 starts with operation 802, in which a substrate is loaded into the processing chamber and supported by a susceptor of a substrate support assembly. At operation 804, the susceptor and the substrate are rotated by an actuator. At operation 806, a deposition gas is flowed into the processing chamber. The deposition gas is configured to form an EPI film on the substrate. At operation 808, an auxiliary gas is flowed toward an edge area of the substrate, the auxiliary gas including a dilution gas configured to dilute the deposition gas. At operation 810, a surface area of the substrate is heated with a first radiant heater pointing toward the surface area of the substrate. At operation 812, the edge area of the substrate is heated with a second radiant heater pointing toward an edge area of the substrate.

In certain embodiments, the method 800 may further include flowing the auxiliary gas from a side gas channel disposed substantially at a same level as the susceptor, separating the auxiliary gas and the deposition gas by a separator coupled to a side wall of the processing chamber; and/or flowing the auxiliary gas from an elevated gas channel disposed above the susceptor. The method 800 may further include flowing a purge gas toward the edge area of the substrate from a space under the susceptor and via a slit disposed in a peripheral area of the susceptor. The method 800 may further include measuring a temperature of the edge area by a first pyrometer disposed around a peripheral area of a lid of the processing chamber; and controlling the second radiant heater to cause the temperature of the edge area to be lower than that of the surface area. The method 800 may further include flowing an etchant gas toward the edge area of the substrate from an etchant gas channel disposed adjacent to an exhaust outlet of the processing chamber.

Although operations of the method 800 are described in order, such operations may be configured to operate in alternate orders. In other words, any order or order of operations set forth in the method 800 inherently does not imply a requirement that the operations be performed in that order. The operations of the method may actually be performed in any order. Further, some operations may be performed concurrently. For example, the auxiliary gas and the deposition gas may be flowed into the processing chamber simultaneously or sequentially. Heating the surface area and the edge area of the substrate may occur before the deposition gas is flowed into the processing chamber. Heating the surface area and the edge area may be applied in a continuous manner or in an intermittent manner.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and take into account experimental error and variations that would be expected by a person having ordinary skill in the art.

As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a substrate support assembly comprising a susceptor configured to support a substrate within a processing region within the processing chamber;
a deposition gas channel configured to flow a deposition gas across an upper surface of the substrate;
an auxiliary gas channel configured to flow an auxiliary gas toward an edge area of the substrate; and
a separator disposed between the deposition gas channel and the auxiliary gas channel.

2. The processing chamber of claim 1, wherein the auxiliary gas channel is disposed between an upper surface of the susceptor and the deposition gas channel.

3. The processing chamber of claim 2, wherein the separator extends from a sidewall of the processing chamber over an outer radial edge of the susceptor.

4. The processing chamber of claim 3, wherein the separator extends from a sidewall of the processing chamber over at least a portion of an edge ring that surrounds the susceptor.

5. The processing chamber of claim 1, wherein the auxiliary gas comprises a dilution gas, and the flow of dilution gas toward the edge area inhibits deposition gas flow on the edge area.

6. The processing chamber of claim 5, wherein the dilution gas comprises SiH₄, Si₂H₆, H₂SiCl₂, HCl, Cl₂, H₂, N₂, or He.

7. The processing chamber of claim 1, further comprising:
an auxiliary heater disposed around a peripheral area within the processing chamber and positioned to radiantly heat the edge area of the substrate.

8. The processing chamber of claim 7, further comprising:
a first pyrometer disposed in the peripheral area and configured to detect a temperature at the edge area of the substrate.

9. The processing chamber of claim 1, further comprising an etchant gas channel configured to flow an etchant gas toward the edge area of the substrate, wherein the etchant gas channel is disposed adjacent to an exhaust outlet of the processing chamber.

10. The processing chamber of claim 1, further comprising:
a purge gas channel configured to flow a purge gas into a space below the susceptor, wherein the susceptor has a plurality of apertures disposed in a peripheral area thereof and configured to allow the purge gas to pass through to the edge area of the substrate.

11. A processing chamber, comprising:
a substrate support assembly comprising a susceptor configured to support a substrate within a processing region within the processing chamber;
a deposition gas channel configured to flow a deposition gas across an upper surface of the substrate;
an auxiliary gas channel; and
a gas distribution plate positioned above the susceptor, wherein:
the auxiliary gas channel is configured to flow the auxiliary gas into a plenum above the gas distribution plate, and
the gas distribution plate has a plurality of gas conduits positioned to flow the auxiliary gas from the plenum toward an edge area of the substrate.

12. The processing chamber of claim 11, wherein the plurality of gas conduits are positioned only in an outer peripheral area of the gas distribution plate.

13. The processing chamber of claim 12, wherein the plurality of gas conduits are configured to direct the auxiliary gas to the outer 2 mm of the substrate.

14. The processing chamber of claim 13, wherein the gas distribution conduits are angled between about 5 degrees and about 45 degrees with respect to a vertical axis of the susceptor.

15. The processing chamber of claim 11, further comprising:
an auxiliary heater disposed around a peripheral area within the processing chamber and positioned to radiantly heat the edge area of the substrate.

16. The processing chamber of claim 11, wherein the auxiliary gas comprises a dilution gas, and the flow of dilution gas toward the edge area inhibits deposition gas flow on the edge area.

17. A processing chamber, comprising:
a substrate support assembly comprising a susceptor configured to support a substrate within a processing region within the processing chamber;
a deposition gas channel configured to flow a deposition gas across an upper surface of the substrate; and
a purge gas channel configured to flow a purge gas into a space below the susceptor, wherein the susceptor has a plurality of apertures disposed in a peripheral area thereof and configured to allow the purge gas to pass through to the edge area of the substrate positioned on the susceptor.

18. The processing chamber of claim 17, wherein the purge gas channel comprises a dispensing pipe extending into the space below the susceptor, wherein the dispensing pipe has orifices configure to direct the purge gas toward the edge area of the substrate.

19. The processing chamber of claim 17, wherein the susceptor comprises:
a pedestal region configured to support the substrate at an outer periphery of the substrate; and
an edge wall surrounding the pedestal region and extending above the pedestal region, wherein the plurality of apertures are disposed in the pedestal region at locations along an inner perimeter of the edge wall radially outward of the substrate.

20. The processing chamber of claim 19, wherein the plurality of apertures are located less than 3 mm from the radial edge of the substrate.
